(19) United States
(12) Patent Application Publication
(10) Pub. No.: US 2012/0031665 A1
(43) Pub. Date: Feb. 9, 2012

(54) ELECTRONIC DEVICE HOUSING

(75) Inventors: BIN DAI, ShenZhen City (CN); FA-GUANG SHI, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 12/964,915

(22) Filed: Dec. 10, 2010

(30) Foreign Application Priority Data
Aug. 3, 2010 (CN) 201010244134.X

(51) Int. Cl. H05K 5/00

(52) U.S. Cl. 174/561

(57) ABSTRACT

An electronic device housing includes a first housing and a second housing. The first housing forms a welding portion. The second housing defines a receiving groove in the periphery for receiving the welding portion. The welding portion is welded to an inner wall of the receiving groove of the second housing.

### BACKGROUND

1. Technical Field

The present disclosure relates generally to electronic device housings and, more particularly, to an electronic device housing formed by welding.

2. Description of Related Art

Referring to FIGS. 6 and 7, a typical electronic device housing 10 includes a bottom housing 11 and a top cover 11. The periphery of the top cover 12 is welded to the bottom housing 11. The top cover 12 and the bottom housing 11 are held together by a clamping member (not shown) during welding.

However, the top cover 11 easily deviates from the clamped welding position because the top cover 11 is smooth and can drift during welding. As a result, the electronic device housing 10 can present a poor appearance after welding. In addition, the top cover 12 is only welded to the bottom housing 11 along the periphery thereof, such that mechanical strength of the electronic device housing 10 is relatively low.

Therefore, there is room for improvement within the art.

### BRIEF DESCRIPTION OF THE DRAWINGS

The components in the drawings are not necessarily drawn to scale, the emphasis instead placed upon clearly illustrating the principles of the present disclosure. Moreover, in the drawings, like reference numerals designate corresponding parts throughout the several views.

FIG. 1 is an isometric view of a first embodiment of an electronic device housing.

FIG. 2 is a partial cross-section of the electronic device housing of FIG. 1, taken along the line II-II.

FIG. 3 an exploded, isometric view of the electronic device housing of FIG. 1.

FIG. 4 is a partial cross-section of a second embodiment of an electronic device housing.

FIG. 5 is an exploded view of the electronic device housing of FIG. 4.

FIG. 6 is an isometric view of a commonly used electronic device housing.

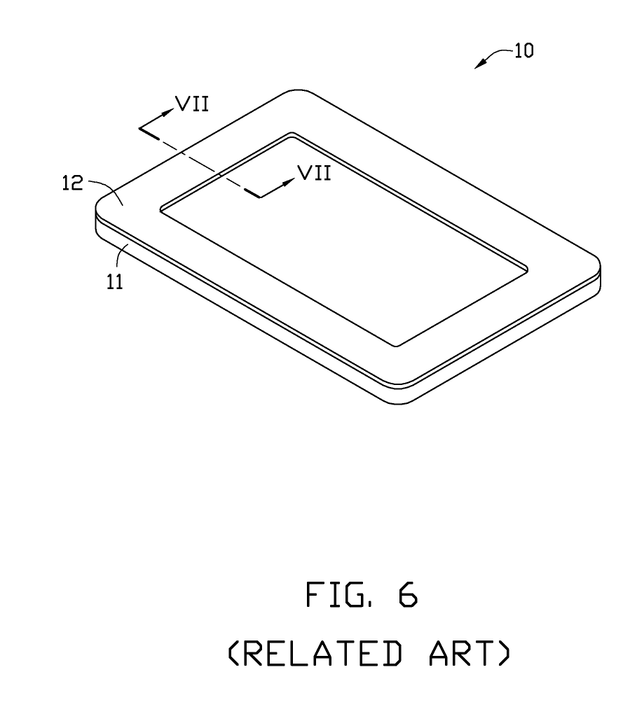

FIG. 7 is a partial cross-section of the electronic device housing of FIG. 6, taken along the line VII-VII.

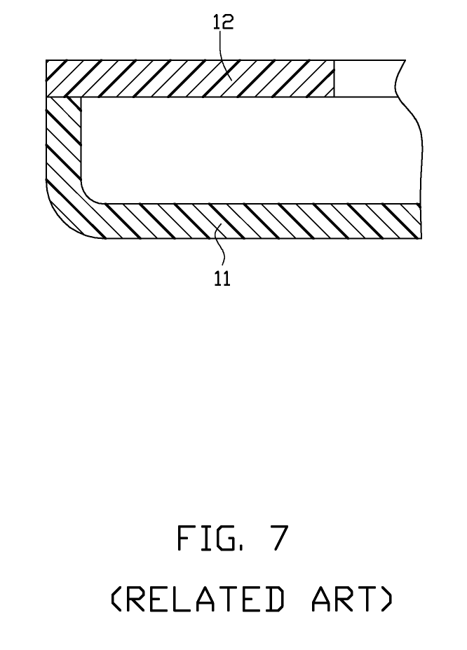

### DETAILED DESCRIPTION

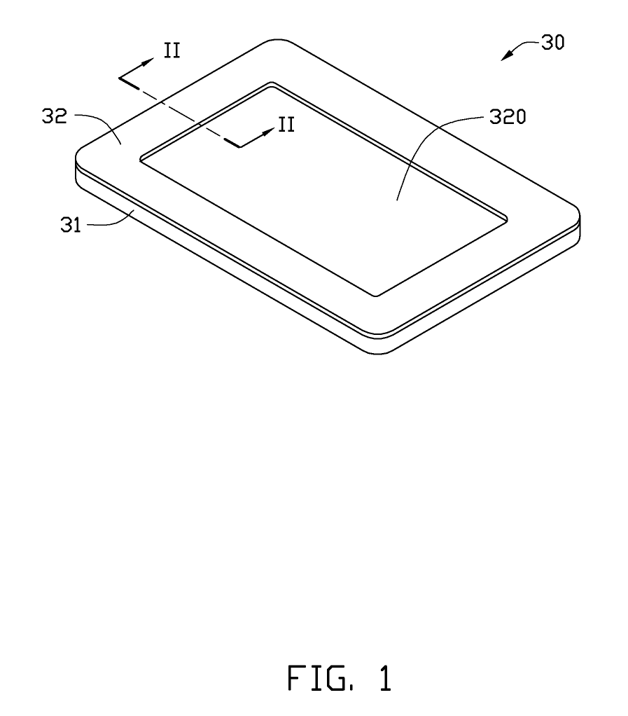

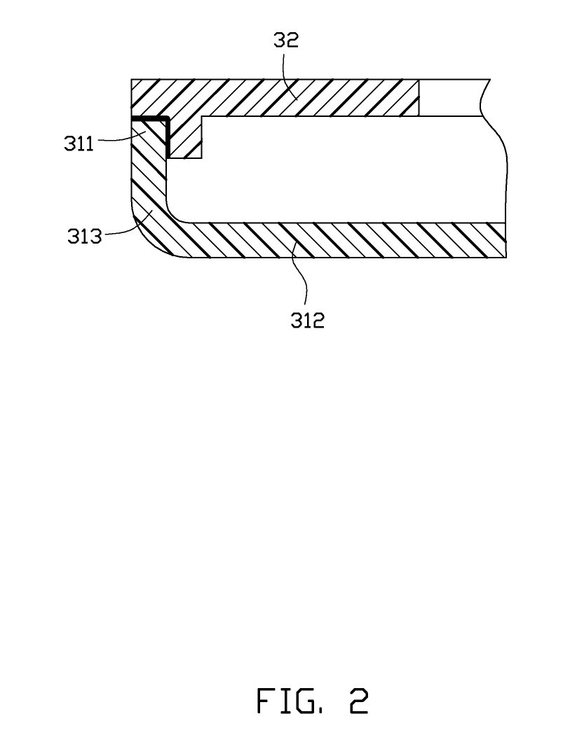

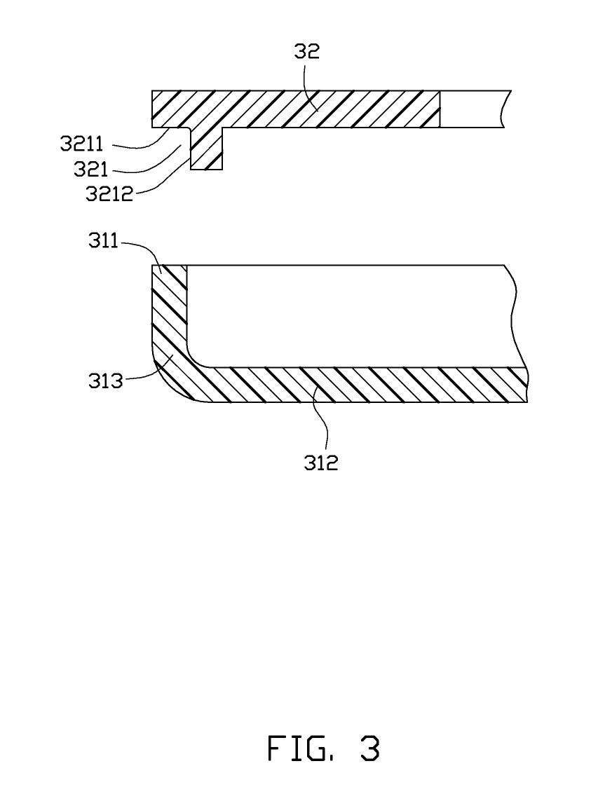

Referring to FIGS. 1 through 3, a first embodiment of an electronic device housing 30 includes a first housing 31 and a second housing 32. In the illustrated embodiment, the first housing 31 is a bottom housing, and the second housing 32 is a top cover. The second housing 32 defines an assembly hole 320 for receiving the display panel (not shown).

The first housing 31 forms a welding portion 311. A cross-section of the welding portion 311 is substantially rectangular. In the illustrated embodiment, the first housing 31 includes a rectangular bottom plate 312 and a side plate 313 extending from an edge of the bottom plate 312. The welding portion 311 is formed at the top end of the side plate 313. The welding portion 311 is a substantially rectangular frame.

The second housing 32 defines a receiving groove 321 in the periphery for receiving the welding portion 311. An inner wall of the receiving groove 321 is defined by a first welding surface 3211 and a second welding surface 3212 welded to the welding portion 311. In the illustrated embodiment, the first welding surface 3211 and the second welding surface 3212 are planes. The first welding surface 3211 is substantially perpendicular to the second welding surface 3212.

In welding the electronic device housing 30, the first housing 31 and the second housing 32 can be held together by a clamping member (not shown). The clamping member with the first housing 31 and the second housing 32 is placed in a welding device (not shown). The welding portion 311 of the first housing 31 is positioned in the receiving groove 321 of the second housing 31, and the welding portion 311 is attached to the first welding surface 3211 and the second welding surface 3212. By design, the first housing 31 cannot slide relative to the second housing 32, that is, the first housing 31 and the second housing 32 will not deviate from the predetermined position. Therefore, the electronic device housing 30 can be welded by the welding device accurately, and thus the electronic device housing 30 has a good appearance. In addition, the first welding surface 3211 and the second welding surface 3212 effectively increase the welding area between the first housing 31 and the second housing 32, thus the electronic device housing 30 has high mechanical strength. Furthermore, the second surface 3212 prevents burn through inside the electronic device housing 30 from the welding process such as electron beam welding.

It should be appreciated that the first housing 31 can be the top cover, and the second housing can be the bottom housing welded to the top cover. The welding portion 311 may be other shapes, such as a circular frame.

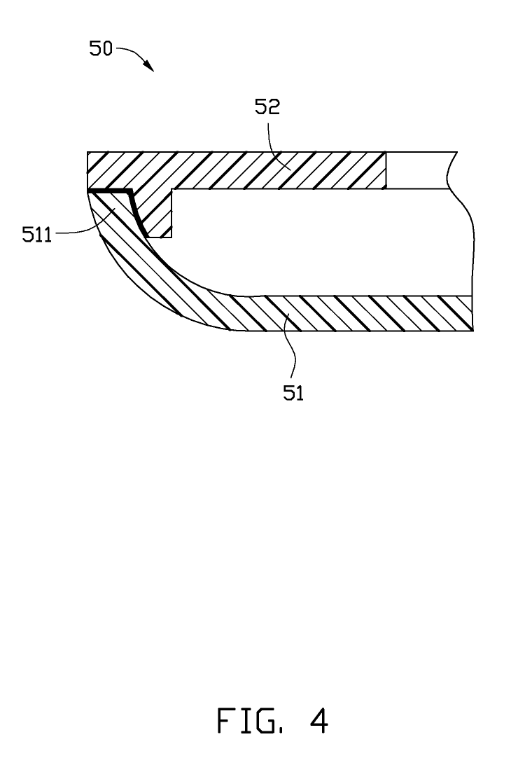

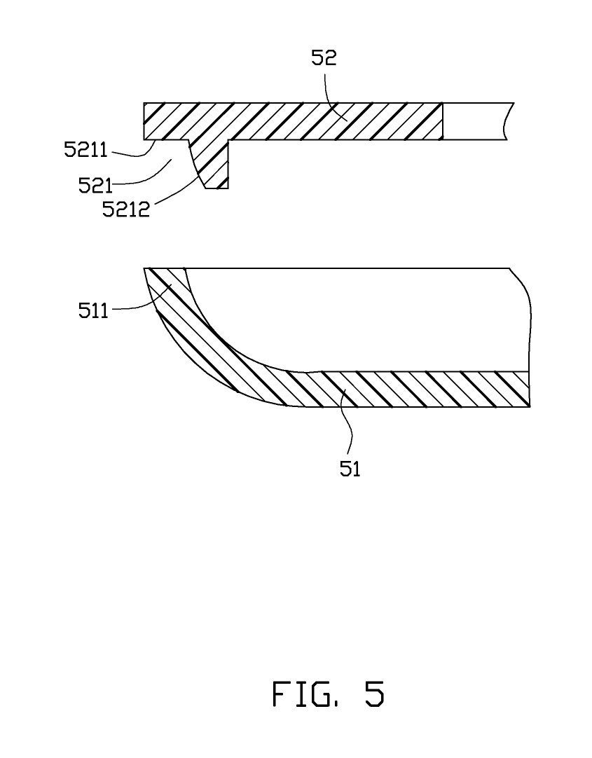

Referring to FIGS. 4 and 5, a second embodiment of an electronic device housing 50 is similar in principle to the electronic device housing 30, except that a welding portion 511 of a first housing 51 has a curved cross-section. An inner wall of a receiving groove 521 is defined by a first welding surface 5211 and a second welding surface 5212 of the second housing 52. The first welding surface 5211 is planar, and the second welding surface 5212 is curved. The receiving groove 521 conforms to the shape of the welding portion 511. Because the second welding surface 5212 is curved, a welding area between the first housing 51 and the second housing 52 further increases. As a result, the mechanical strength of the electronic device housing 50 is enhanced. In an alternative embodiment, the first welding surface 5211 is also curved.

It is believed that the present embodiments and their advantages will be understood from the foregoing description, and it will be apparent that various changes may be made thereto without departing from the spirit and scope of the disclosure or sacrificing all of its material advantages.

What is claimed is:

1. An electronic device housing, comprising:
a first housing forming a welding portion; and
a second housing defining a receiving groove in the periphery for receiving the welding portion, wherein the welding portion is welded to an inner wall of the receiving groove.

2. The electronic device housing of claim 1, wherein a cross-section of the welding portion is arc shaped.

3. The electronic device housing of claim 1, wherein a cross-section of the welding portion is rectangular.

4. The electronic device housing of claim 1, wherein the welding portion is a substantially rectangular frame.

5. The electronic device housing of claim 1, wherein the inner wall in the receiving groove forms a first welding surface and a second surface, both of which are welded to the welding portion.

6. The electronic device housing of claim 5, wherein the first welding surface is a plane, and the second welding surface is curved.

7. The electronic device housing of claim 5, wherein the first welding surface and the second surface are planes, and substantially perpendicular to each other.

8. The electronic device housing of claim 1, wherein the second housing defines an assembly hole for receiving the display panel.

9. The electronic device housing of claim 1, wherein the first housing comprises a bottom plate and a side plate extending from an edge of the bottom plate.

10. The electronic device housing of claim 9, wherein the welding portion is formed at a top end of the side plate.
